(19) United States
(12) Patent Application Publication
(10) Pub. No.: US 2018/0253000 A1
(43) Pub. Date: Sep. 6, 2018

(54) PATTERN FORMING METHOD, IMPRINT APPARATUS, MANUFACTURING METHOD AND MIXING METHOD

(71) Applicant: CANON KABUSHIKI KAISHA, Tokyo (JP)

(72) Inventors: Tomohiro Saito, Utsunomiya-shi (JP); Toshiki Ito, Kawasaki-shi (JP); Hiroshi Kurosawa, Utsunomiya-shi (JP)

(21) Appl. No.: 15/893,408

(22) Filed: Feb. 9, 2018

Related U.S. Application Data
(60) Provisional application No. 62/467,699, filed on Mar. 6, 2017.

(51) Int. Cl. G03F 7/00

(52) U.S. Cl. CPC G03F 7/0002

(57) ABSTRACT

A pattern forming method of forming a pattern on a substrate by using a mold includes a step of supplying a curable composition onto a liquid film formed on a substrate, a step of vibrating the substrate so as to mix together a composition of the liquid film and the curable composition, a step of bringing a mixture into contact with the mold, the mixture being provided by vibrating the substrate to cause mixing, and a step of curing the mixture being in contact with the mold to form a pattern.

### BACKGROUND OF THE INVENTION

With an increase demand for a reduction in dimensions in semiconductor devices, MEMS, and the like, the photo-nanoimprint technology has been attracting attention as a microprocessing technology. In the photo-nanoimprint technology, while a mold (mold) having a fine irregular pattern in the surface is pressed onto a substrate (wafer) coated with a photocurable composition (resist), the photocurable composition is cured. In this way, the irregular pattern of the mold is transferred to the cured film of the photocurable composition, to form a pattern on the substrate. The photo-nanoimprint technology enables formation of fine structures on the order of several nanometers on substrates.

The photo-nanoimprint technology in Japanese Patent No. 4791357 will be described with reference to FIG. 1. In a pattern formation region on a substrate 101, a resist 102 in liquid form is first discretely dropped by an inkjet method (placement step, FIG. 1[1]). The resist droplets formed by dropping spread over the substrate. This phenomenon is referred to as pre-spread (103 in FIG. 1[1]). Subsequently, this resist is molded with a mold (mold) 105 that has a pattern and is transparent to irradiation light described later (mold contact step, FIG. 1[2]). In the mold contact step, the resist droplets spread, by capillarity, throughout the gap region between the substrate and the mold (104 in FIG. 1[2]). This phenomenon is referred to as spread. In the mold contact step, the resist also fills the upper recess portions of the mold by capillarity (104 in FIG. 1[2]). This filling phenomenon is referred to as fill. The time taken for completion of spread and fill is referred to as filling time. After completion of filling with the resist, the resist is cured by being irradiated with light 106 (light irradiation step, FIG. 1[3]). Subsequently, the resist and the mold are separated from each other (mold release step, FIG. 1[4]). These steps are performed to form a resist pattern having a predetermined profile (photocured film, 107 in FIG. 1[4]) on the substrate. In the photo-nanoimprint technology described in Japanese Patent No. 4791357, a long time (filling time) is taken from the initiation of contact with the mold to completion of spread and fill, and the throughput is low, which has been problematic.

### SUMMARY OF THE INVENTION

A pattern forming method according to an aspect of the present invention for solving the above-described problem is a pattern forming method of forming a pattern on a substrate by using a mold, the pattern forming method including a step of supplying a curable composition onto a liquid film formed on a substrate, a step of vibrating the substrate so as to mix together a composition of the liquid film and the curable composition, a step of bringing a mixture into contact with the mold, the mixture being provided by vibrating the substrate to mix together the composition of the liquid film and the curable composition, and a step of curing the mixture being in contact with the mold to form a pattern.

Further features of the present invention will become apparent from the following description of exemplary embodiments with reference to the attached drawings.

### BRIEF DESCRIPTION OF THE DRAWINGS

FIG. 1 is an explanatory view of SST-NIL technology.

FIG. 2 is an explanatory view of a pattern forming method according to a first embodiment.

FIG. 3 is an explanatory view of a pattern forming method according to a first embodiment.

FIG. 4 is an explanatory view of a pattern forming method according to a second embodiment.

FIG. 5 illustrates the relationship between a shot region and a liquid contact region.

FIG. 6A schematically illustrates an imprint apparatus. FIG. 6B illustrates the control system of the imprint apparatus.

FIG. 7 is an explanatory view of a pattern forming method according to a first embodiment.

FIG. 8 is a flowchart of a pattern forming method.

### DESCRIPTION OF THE EMBODIMENTS

### First Embodiment

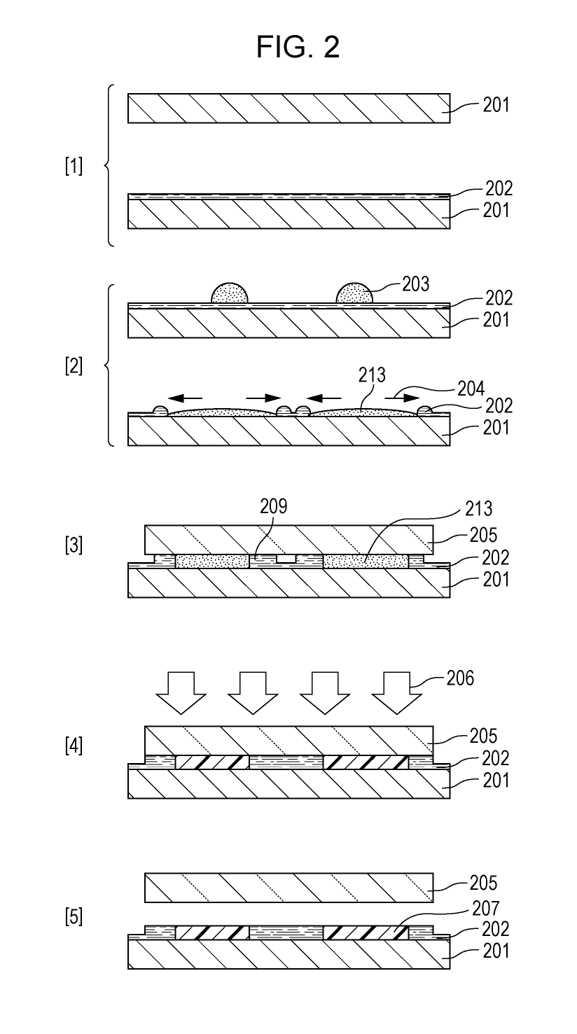

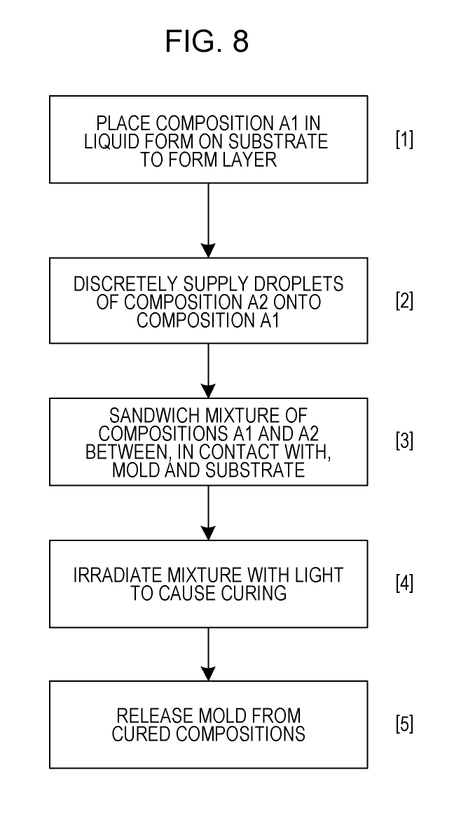

Hereinafter, the embodiment will be described with appropriately referring to drawings. This embodiment relates to a photo-nanoimprint technology in which the filling time is short, in other words, the throughput is high (Short Spread Time Nanoimprint Lithography, hereafter SST-NIL). SST-NIL will be described with the schematic sectional view in FIG. 2 and the flowchart in FIG. 8.

A pattern forming method according to this embodiment includes Step [1] to Step [5]. On a substrate 201, a composition (A1) in liquid form is first placed to form a layer (layer formation step [1]). As a result, on the substrate 201, a liquid film 202 of the composition (A1) 202 is formed. Subsequently, on the liquid film 202 of the composition (A1), droplets 203 of a composition (A2) are discretely supplied (ejected) (supply step [2]). The droplets 203 of the composition (A2) dropped on the liquid film 202 of the composition (A1) then mix with the composition (A1) and also spread in a direction denoted by 204. Subsequently, a mixture 213 provided by mixing of the composition (A1) and the composition (A2) is sandwiched between, also in contact with, a mold (mold) 205 having a pattern and the substrate 201 (mold contact step [3]). At this time, the mold 205 is brought into contact with the mixture 213 to achieve imprinting on the mixture 213. In addition, alignment control is performed by determining the relative position between the alignment mark of the mold 205 and an alignment mark on the substrate 201. The alignment is achieved by controlling the position of a substrate stage holding the substrate or a mold stage holding the mold. The alignment may also be achieved by controlling a mechanism of applying force to the mold to change the shape of the mold, or by controlling the shape of a shot region by application of heat to the substrate. Subsequently, the mixture 213 provided by mixing of the two compositions is irradiated with, from its mold side, light 206 to cure the mixture 213 (light irradiation step [4]). Subsequently, the mold 205 is released from the cured composition layer to obtain a cured pattern 207 (mold release step [5]). Such a series of steps including Step [1] to Step [5] (pattern forming process) can provide a cured film having a desired irregular pattern profile (pattern profile corresponding to the irregular profile of the mold) at a desired position. Incidentally, hereafter, a step unit in which Step [2] to Step [5] are performed in series will be referred to as “shot”; and a region of the compositions (A1) and (A2) that comes into contact with the mold, in other words, a region in which a pattern is formed on the substrate will be referred to as a “shot region”.

In SST-NIL, the droplets of the composition (A2) discretely dropped spread rapidly, compared with conventional cases, on the liquid film or within the liquid film of the composition (A1), to thereby achieve a short filling time and a high throughput. However, between a droplet and a droplet of the composition (A2) 203, a region 209 having a high concentration of the composition (A1) may be generated. The central portions of the droplets of the composition (A2) may have a high concentration of the composition (A2). The cured film 207 having a pattern profile, in other words, a cured product of the mixture of the composition (A1) and the composition (A2), may be used as a dry etching mask when the substrate 201 is processed by dry etching. In this case, because of the above-described nonuniform concentration, the cured film 207 may have nonuniform dry etching resistance. For this reason, the composition (A1) is required to have dry etching resistance at least equivalent to that of the composition (A2). The composition (A1) is required to have not only dry etching resistance, but also a relatively low viscosity in order to exert the high throughput effect of SST-NIL.

### Compositions

A component (a) contained in the composition (A1) will be referred to as a component (a1). A component (a) contained in the composition (A2) will be referred to as a component (a2). The same applies to a component (b) to a component (d). The compositions (A1) and (A2) according to this embodiment are compounds at least containing a component (a) that is a polymerizable compound. The compositions (A1) and (A2) may further contain a component (b) that is a photopolymerization initiator, a non-polymerizable compound (c), and a component (d) that is a solvent.

The term “cured film” in the Description means a film formed by polymerizing a composition to cause curing on a substrate. The cured film is not particularly limited in terms of shape, and may have a pattern profile in the surface.

Hereinafter, the components will be described in detail.

### Component (a): Polymerizable Compound

The component (a) is a polymerizable compound. The term “polymerizable compound” in the Description denotes a compound that reacts with a polymerizing factor (such as a radical) generated from a photopolymerization initiator (component (b)) to cause a chain reaction (polymerization reaction) to thereby form a polymer film.

Examples of such polymerizable compounds include radical polymerizable compounds. The polymerizable compound serving as the component (a) may be constituted by a single polymerizable compound alone, or may be constituted by a plurality of polymerizable compounds.

The radical polymerizable compounds are preferably compounds that have one or more acryloyl groups or methacryloyl groups, namely, (meth)acrylic compounds. Thus, in the composition according to this embodiment, the component (a) preferably contains a (meth)acrylic compound; more preferably, the component (a) contains, as the main component, a (meth)acrylic compound; most preferably, the component (a) is a (meth)acrylic compound. Incidentally, the phrase “the component (a) contains, as the main component, a (meth)acrylic compound” used here means that 90 weight % or more of the component (a) is a (meth)acrylic compound.

When such a radical polymerizable compound is constituted by a plurality of compounds having one or more acryloyl groups or methacryloyl groups, it preferably contains a monofunctional (meth)acrylic monomer and a polyfunctional (meth)acrylic monomer. This is because combination of a monofunctional (meth)acrylic monomer and a polyfunctional (meth)acrylic monomer provides a cured film having a high mechanical strength.

Non-limiting examples of the monofunctional (meth)acrylic compound having an acryloyl group or methacryloyl group include phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylene nonylphenyl ether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloyl morpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxy diethylene glycol (meth)acrylate, polyethylene glycol mono(meth)acrylate, polypropylene glycol mono(meth)acrylate, methoxyethylene glycol (meth)acrylate, ethoxyethyl (meth)acrylate, methoxypolyethylene glycol (meth)acrylate, methoxypolypropylene glycol (meth)acrylate, diacetone(meth)acrylamide, isobutoxymethyl(meth)acrylamide, N,N-dimethyl(meth)acrylamide, t-octyl(meth)acrylamide, dimethylaminoethyl (meth)acrylate, diethylaminoethyl (meth)acrylate, 7-amino-3,7-dimethyloctyl (meth)acrylate, N,N-diethyl(meth)acrylamide, and N,N-dimethylaminopropyl(meth)acrylamide.

Non-limiting examples of commercially available products of the above-described monofunctional (meth)acrylic compounds include ARONIX (registered trademark) M101, M102, M110, M111, M113, M117, M5700, TO-1317, M120, M150, M156 (all manufactured by TOAGOSEI CO., LTD.), MEDOL10, MIBDOL10, CHDOL10, MMDOL30, MEDOL30, MIBDOL30, CHDOL30, LA, IBXA, 2-MTA, HPA, VISCOAT #150, #155, #158, #190, #192, #193, #220, #2000, #2100, #2150 (all manufactured by OSAKA ORGANIC CHEMICAL INDUSTRY LTD.), LIGHT ACRYLATE BO-A, EC-A, DMP-A, THF-A, HOP-A, HOA-MPE, HOA-MPL, PO-A, P-200A, NP-4EA, NP-8EA, EPOXY ESTER M-600A (all manufactured by Kyoeisha Chemical Co., Ltd.), KAYARAD (registered trademark) TC110S, R-564, R-128H (all manufactured by Nippon Kayaku Co., Ltd.), NK ESTER AMP-10G, AMP-20G (all manufactured by Shin Nakamura Chemical Co., Ltd.), FA-511A, 512A, 513A (all manufactured by Hitachi Chemical Company, Ltd.), PHE, CEA, PHE-2, PHE-4, BR-31, BR-31M, BR-32 (all manufactured by DAI-ICHI KOGYO SEIYAKU CO., LTD.), VP (manufactured by BASF), ACMO, DMAA, and DMAPAA (all manufactured by KOHJIN Co., Ltd.).

Non-limiting examples of the polyfunctional (meth)acrylic compound having two or more acryloyl groups or methacryloyl groups include trimethylolpropane di(meth)acrylate, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, dimethyloltricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydroxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, and EO, PO-modified 2,2-bis(4-((meth)acryloxy)phenyl)propane.

Non-limiting examples of commercially available products of the above-described polyfunctional (meth)acrylic compounds include Yupimer (registered trademark) UV SA1002, SA2007 (all manufactured by Mitsubishi Chemical Corporation), VISCOAT #195, #230, #215, #260, #335HP, #295, #300, #360, #700, GPT, 3PA (all manufactured by OSAKA ORGANIC CHEMICAL INDUSTRY LTD.), LIGHT ACRYLATE 4EG-A, 9EG-A, NP-A, DCP-A, BP-4EA, BP-4PA, TMP-A, PE-3A, PE-4A, DPE-6A (all manufactured by Kyoeisha Chemical Co., Ltd.), KAYARAD (registered trademark) PET-30, TMPTA, R-604, DPHA, DPCA-20, -30, -60, -120, HX-620, D-310, D-330 (all manufactured by Nippon Kayaku Co., Ltd.), ARONIX (registered trademark) M208, M210, M215, M220, M240, M305, M309, M310, M315, M325, M400 (all manufactured by TOAGOSEI CO., LTD.), Ripoxy (registered trademark) VR-77, VR-60, and VR-90 (all manufactured by Showa Highpolymer Co., Ltd.).

In the above-described compound group, the term “(meth)acrylate” means an acrylate or a methacrylate that has an alcohol residue equivalent to that of the acrylate. The term “(meth)acryloyl group” means an acryloyl group or a methacryloyl group that has an alcohol residue equivalent to that of the acryloyl group. The term “EO” denotes ethylene oxide. The term “EO-modified compound A” denotes a compound in which the (meth)acrylic acid residue and the alcohol residue of the compound A are bonded together via a block structure of ethylene oxide groups. The term “PO” denotes propylene oxide. The term “PO-modified compound B” denotes a compound in which the (meth)acrylic acid residue and the alcohol residue of the compound B are bonded together via a block structure of propylene oxide groups.

### Component (b): Photopolymerization Initiator

The component (b) is a photopolymerization initiator. The term “photopolymerization initiator” in the Description denotes a compound that generates the polymerizing factor (radical) in response to light at a predetermined wavelength. Specifically, the photopolymerization initiator is a polymerization initiator (radical generator) that generates a radical in response to light (infrared radiation, visible radiation, ultraviolet radiation, far-ultraviolet radiation, X-rays, charged particle beams such as an electron beam, or radiation).

The component (b) may be constituted by a single photopolymerization initiator, or may be constituted by a plurality of photopolymerization initiators.

Non-limiting examples of the radical generator include 2,4,5-triarylimidazole dimers that may have a substituent such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, and 2-(o- or p-methoxyphenyl)-4,5-diphenylimidazole dimer; benzophenone derivatives such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-aminoaromatic ketone derivatives such as 2-benzyl-2-dimethylamino-1-(4-morpholinophenyl)-butanone-1, and 2-methyl-1-[4-(methylthio)phenyl]-2-morpholino-propan-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone, and 2,3-dimethylanthraquinone; benzoin ether derivatives such as benzoin methyl ether, benzoin ethyl ether, and benzoin phenyl ether; benzoin derivatives such as benzoin, methylbenzoin, ethylbenzoin, and propylbenzoin; benzyl derivatives such as benzyl dimethyl ketal; acridine derivatives such as 9-phenylacridine, and 1,7-bis(9,9′-acridinyl)heptane; N-phenylglycine derivatives such as N-phenylglycine; acetophenone derivatives such as acetophenone, 3-methylacetophenone, acetophenone benzyl ketal, 1-hydroxycyclohexyl phenyl ketone, and 2,2-dimethoxy-2-phenylacetophenone; thioxanthone derivatives such as thioxanthone, diethyl thioxanthone, 2-isopropyl thioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthio)-,2-(O-benzoyloxime)], ethanone, and 1-[9-ethyl-6-(2-methylbenzoyl)-9H-carbazol-3-yl]-,1-(O-acetyloxime); xanthone, fluorenone, benzaldehyde, fluorene, anthraquinone, triphenylamine, carbazole, 1-(4-isopropylphenyl)-2-hydroxy-2-methylpropan-1-one, and 2-hydroxy-2-methyl-1-phenylpropan-1-one.

Non-limiting examples of commercially available products of the above-described radical generators include Irgacure 184, 369, 651, 500, 819, 907, 784, 2959, CGI-1700, -1750, -1850, CG24-61, Darocur 1116, 1173, Lucirin (registered trademark) TPO, LR8893, LR8970 (all manufactured by BASF), and EBECRYL P36 (manufactured by UCB).

Of these, the component (b) is preferably an acylphosphine oxide-based polymerization initiator. Incidentally, among the above-described examples, such acylphosphine oxide-based polymerization initiators are acylphosphine oxide compounds such as 2,4,6-trimethylbenzoyldiphenylphosphine oxide, bis(2,4,6-trimethylbenzoyl)phenylphosphine oxide, and bis(2,6-dimethoxybenzoyl)-2,4,4-trimethylpentylphosphine oxide.

In this embodiment, the composition (A1) preferably has substantially no photoreactivity. Thus, the mixing ratio of the component (b) that is a photopolymerization initiator in the composition (A1) relative to the total of the component (a), the component (b), and the component (c) described later, in other words, relative to the total weight of all the components except for the solvent component (d), is set to 0 weight % or more and less than 0.1 weight %, preferably 0.01 weight % or less, more preferably 0.001 weight % or less. Incidentally, the term “0 weight %” means that the composition (A1) contains no photopolymerization initiator.

In the composition (A1), when the mixing ratio of the component (b) relative to the total of the component (a), the component (b), and the component (c) is set to less than 0.1 weight %, the composition (A1) has substantially no photoreactivity. Thus, leakage light does not cause photocuring, so that, also in the neighboring shots, even in a short filling time, a pattern having a small number of unfilled defects is obtained. The curing reaction of the composition (A1) in the present shot will be described later.

The mixing ratio (content) of the component (b) that is a photopolymerization initiator in the composition (A2) relative to the total of the component (a), the component (b), and the component (c) described later, in other words, relative to the total weight of all the components except for the solvent component (d), may be 0.1 weight % or more and 50 weight % or less, preferably 0.1 weight % or more and 20 weight % or less, more preferably more than 10 weight % and 20 weight % or less.

When the mixing ratio of the component (b) in the composition (A2) relative to the total of the component (a), the component (b), and the component (c) is set to 0.1 weight % or more, the curing rate of the composition is increased, to thereby enhance the reaction efficiency. When the mixing ratio of the component (b) relative to the total of the component (a), the component (b), and the component (c) is set to 50 weight % or less, the resultant cured film can be provided as a cured film having a relatively high mechanical strength.

### Component (c): Non-Polymerizable Compound

The compositions (A1) and (A2) according to this embodiment may contain, in addition to the above-described component (a) and component (b), a non-polymerizable compound as a component (c) in accordance with various purposes as long as advantages of the present invention are not degraded. Examples of such a component (c) include a compound that does not have a polymerizable functional group such as a (meth)acryloyl group, and that does not have the capability of generating the polymerizing factor (radical) in response to light at a predetermined wavelength: for example, a sensitizer, a hydrogen donor, an internally added release agent, a surfactant, an antioxidant, a polymer component, and other additives. As the component (c), two or more of the compounds may be contained.

The sensitizer is a compound appropriately added for the purpose of promoting a polymerization reaction or increasing the reaction conversion. The sensitizer is, for example, a sensitizing dye.

The sensitizing dye is a compound that is excited due to absorption of light at a predetermined wavelength, and interacts with a photopolymerization initiator serving as the component (b). Incidentally, the term “interact” used here denotes, for example, energy transfer or electron transfer from the excited sensitizing dye to the photopolymerization initiator serving as the component (b).

Non-limiting specific examples of the sensitizing dye include anthracene derivatives, anthraquinone derivatives, pyrene derivatives, perylene derivatives, carbazole derivatives, benzophenone derivatives, thioxanthone derivatives, xanthone derivatives, coumarin derivatives, phenothiazine derivatives, camphorquinone derivatives, acridine dyes, thiopyrylium salt dyes, merocyanine dyes, quinoline dyes, styrylquinoline dyes, ketocoumarin dyes, thioxanthene dyes, xanthene dyes, oxonol dyes, cyanine dyes, rhodamine dyes, and pyrylium salt dyes.

Such sensitizers may be used alone or in combination of two or more thereof.

The hydrogen donor is a compound that reacts with an initiation radical generated from a photopolymerization initiator serving as the component (b), or a radical at a polymerization propagating end, to generate a more reactive radical. The hydrogen donor is preferably added when the photopolymerization initiator serving as the component (b) is a photoradical generator.

Non-limiting specific examples of the hydrogen donor include amine compounds such as n-butylamine, di-n-butylamine, tri-n-butylphosphine, allylthiourea, s-benzylisothiouronium-p-toluene sulfinate, triethylamine, diethylaminoethyl methacrylate, triethylenetetramine, 4,4′-bis(dialkylamino)benzophenone, ethyl N,N-dimethylaminobenzoate, isoamyl N,N-dimethylaminobenzoate, pentyl-4-dimethylaminobenzoate, triethanolamine, and N-phenylglycine; and mercapto compounds such as 2-mercapto-N-phenylbenzoimidazole, and mercaptopropionate.

Such hydrogen donors may be used alone or in combination of two or more thereof. Such a hydrogen donor may function as a sensitizer.

For the purpose of reducing the interfacial bonding force between the mold and the resist, in other words, reducing a mold release force in the mold release step described later, the internally added release agent may be added to the composition. In the Description, the term “internally added” means addition to the composition before the composition placement step.

Examples of the internally added release agent include surfactants such as silicone surfactants, fluorosurfactants, and hydrocarbon surfactants. Incidentally, in the present invention, the internally added release agent is not polymerizable.

Examples of the fluorosurfactants include polyalkylene oxide (such as polyethylene oxide or polypropylene oxide) adducts of alcohols having a perfluoroalkyl group, and polyalkylene oxide (such as polyethylene oxide or polypropylene oxide) adducts of perfluoropolyether. Incidentally, the fluorosurfactants may have, in a portion of the molecular structure (for example, an end group), a hydroxyl group, an alkoxy group, an alkyl group, an amino group, or a thiol group, for example.

The fluorosurfactants may be commercially available products. Examples of the commercially available products include MEGAFACE (registered trademark) F-444, TF-2066, TF-2067, TF-2068 (all manufactured by DIC Corporation), Fluorad FC-430, FC-431 (all manufactured by Sumitomo 3M Limited), SURFLON (registered trademark) S-382 (manufactured by AGC), EFTOP EF-122A, 122B, 122C, EF-121, EF-126, EF-127, MF-100 (all manufactured by Tohkem Products Corporation), PF-636, PF-6320, PF-656, PF-6520 (all manufactured by OMNOVA Solutions Inc.), UNIDYNE (registered trademark) DS-401, DS-403, DS-451 (all manufactured by DAIKIN INDUSTRIES, LTD.), FTERGENT (registered trademark) 250, 251, 222F, and 208G (all manufactured by NEOS COMPANY LIMITED).

The internally added release agent may be a hydrocarbon surfactant.

Examples of the hydrocarbon surfactant include alkyl alcohol polyalkylene oxide adducts in which alkylene oxides having 2 to 4 carbon atoms are added to alkyl alcohols having 1 to 50 carbon atoms.

Examples of the alkyl alcohol polyalkylene oxide adducts include methyl alcohol ethylene oxide adducts, decyl alcohol ethylene oxide adducts, lauryl alcohol ethylene oxide adducts, cetyl alcohol ethylene oxide adducts, stearyl alcohol ethylene oxide adducts, and stearyl alcohol ethylene oxide/propylene oxide adducts. Incidentally, the end group of such an alkyl alcohol polyalkylene oxide adduct is not limited to a hydroxyl group, which is produced by simply adding a polyalkylene oxide to an alkyl alcohol. This hydroxyl group may be substituted with another substituent, for example, a polar functional group such as a carboxyl group, an amino group, a pyridyl group, a thiol group, or a silanol group, or a hydrophobic functional group such as an alkyl group or an alkoxy group.

The alkyl alcohol polyalkylene oxide adducts may be commercially available products. Examples of the commercially available products include polyoxyethylene methyl ethers (methyl alcohol ethylene oxide adducts) (BLAUNON MP-400, MP-550, MP-1000) manufactured by AOKI OIL INDUSTRIAL Co., Ltd., polyoxyethylene decyl ethers (decyl alcohol ethylene oxide adducts) (FINESURF D-1303, D-1305, D-1307, D-1310) manufactured by AOKI OIL INDUSTRIAL Co., Ltd., polyoxyethylene lauryl ether (lauryl alcohol ethylene oxide adduct) (BLAUNON EL-1505) manufactured by AOKI OIL INDUSTRIAL Co., Ltd., polyoxyethylene cetyl ethers (cetyl alcohol ethylene oxide adducts) (BLAUNON CH-305, CH-310) manufactured by AOKI OIL INDUSTRIAL Co., Ltd., polyoxyethylene stearyl ethers (stearyl alcohol ethylene oxide adducts) (BLAUNON SR-705, SR-707, SR-715, SR-720, SR-730, SR-750) manufactured by AOKI OIL INDUSTRIAL Co., Ltd., randomly polymerized polyoxyethylenepolyoxypropylene stearyl ethers (BLAUNON SA-50/50 1000R, SA-30/70 2000R) manufactured by AOKI OIL INDUSTRIAL Co., Ltd., polyoxyethylene methyl ether (Pluriol (registered trademark) A760E) manufactured by BASF, and polyoxyethylene alkyl ethers (EMULGEN series) manufactured by Kao Corporation.

Of these hydrocarbon surfactants, the internally added release agents are preferably alkyl alcohol polyalkylene oxide adducts, more preferably long-chain alkyl alcohol polyalkylene oxide adducts.

The internally added release agents may be used alone or in combination of two or more thereof.

The mixing ratio of the component (c) that is a non-polymerizable compound in the compositions relative to the total of the component (a), the component (b), and the component (c) described later, in other words, relative to the total weight of all the components except for the solvent, may be 0 weight % or more and 50 weight % or less, preferably 0.1 weight % or more and 50 weight % or less, more preferably 0.1 weight % or more and 20 weight % or less.

When the mixing ratio of the component (c) is set to 50 weight % or less relative to the total of the component (a), the component (b), and the component (c), the resultant cured film can be provided as a cured film having a relatively high mechanical strength.

### Component (d): Solvent

The compositions according to this embodiment may contain a solvent as a component (d). The component (d) is not particularly limited as long as it is a solvent in which the component (a), the component (b), and the component (c) are dissolved. Preferred solvents are solvents having boiling points at ordinary pressure of 80° C. or more and 200° C. or less. More preferred solvents are solvents having at least one of an ester structure, a ketone structure, a hydroxyl group, and an ether structure. Specifically, such a solvent is a single solvent or a mixture of solvents selected from propylene glycol monomethyl ether acetate, propylene glycol monomethyl ether, cyclohexanone, 2-heptanone, γ-butyrolactone, and ethyl lactate.

The composition (A1) according to this embodiment preferably contains the component (d). This is because, as described later, the method of applying the composition (A1) to a substrate is preferably a spin-coating method.

### Temperature of Compositions During Mixing

When the compositions (A1) and (A2) according to this embodiment are prepared, at least the component (a) and the component (b) are mixed together and dissolved under predetermined temperature conditions: specifically, in a range of 0° C. or more and 100° C. or less. The same applies to cases where the component (c) and the component (d) are contained.

### Viscosities of Compositions

The compositions (A1) and (A2) according to this embodiment are preferably liquids. This is because, in the mold contact step described later, spread and fill of the compositions (A1) and/or (A2) rapidly reach completion, in other words, the filling time is short.

In the composition (A1) according to this embodiment, the component mixture except for the solvent (component (d)) preferably has a viscosity at 25° C. of 1 mPa·s or more and 1000 mPa·s or less, more preferably 1 mPa·s or more and 500 mPa·s or less, still more preferably 1 mPa·s or more and 100 mPa·s or less.

In the composition (A2) according to this embodiment, the component mixture except for the solvent (component (d)) preferably has a viscosity at 25° C. of 1 mPa·s or more and 100 mPa·s or less, more preferably 1 mPa·s or more and 50 mPa·s or less, still more preferably 1 mPa·s or more and 12 mPa·s or less.

When the compositions (A1) and (A2) are set to have a viscosity of 100 mPa·s or less, upon contact of the compositions (A1) and (A2) with the mold, spread and fill rapidly reach completion. In other words, the compositions according to this embodiment are used, so that the photo-nanoimprint method can be performed at a high throughput. In addition, pattern defects due to filling failure are less likely to occur.

When the viscosity is set to 1 mPa·s or more, during coating of a substrate with the compositions (A1) and (A2), nonuniform coating is less likely to occur. In addition, during contact of the compositions (A1) and (A2) with a mold, leakage of the compositions (A1) and (A2) from the end portions of the mold is less likely to occur.

### Surface Tension of Compositions

Regarding the surface tension of the compositions (A1) and (A2) according to this embodiment, each composition of the components except for the solvent (component (d)) preferably has a surface tension at 23° C. of 5 mN/m or more and 70 mN/m or less, more preferably 7 mN/m or more and 50 mN/m or less, still more preferably 10 mN/m or more and 40 mN/m or less. The higher the surface tension, for example, 5 mN/m or more, the stronger the capillary force exerted. Thus, upon contact of the composition (A1) and/or (A2) with the mold, filling (spread and fill) reaches completion in a short time.

When the surface tension is set to 70 mN/m or less, the cured film obtained by curing the compositions is a cured film having surface smoothness.

In this embodiment, the surface tension of the composition (A1) except for the solvent (component (d)) is preferably higher than the surface tension of the composition (A2) except for the solvent (component (d)). This is because, before the mold contact step, the Marangoni's effect described later causes an increase in the rate of pre-spread of the composition (A2) (droplets spread over a wide region); the time taken for achieving spread is reduced in the mold contact step described later, and, as a result, the filling time is reduced.

The Marangoni's effect is a phenomenon of movement of the free surface due to the local difference in surface tension of liquid. The difference in surface tension, that is, in surface energy, serves as a driving force to cause a liquid having a low surface tension to spread to cover a larger surface area. Specifically, when the composition (A1) having a high surface tension is applied to the whole surface of the substrate, and subsequently the composition (A2) having a low surface tension is dropped, the rate of pre-spread of the composition (A2) is increased.

### Contact Angle of Compositions

In the compositions (A1) and (A2) according to this embodiment, each composition of components except for the solvent (component (d)) preferably makes a contact angle of 0° or more and 90° or less relative to both of the substrate surface and the mold surface. When the contact angle is more than 90°, within the mold pattern and in the substrate-mold gap, the capillary force is exerted in a negative way (to reduce the mold-composition contact interface), so that filling is not achieved. In particular, the contact angle is preferably 0° or more and 30° or less. The smaller the contact angle, the stronger the capillary force exerted, which results in a higher filling rate.

### Impurities Present in Compositions

The impurity content of the compositions (A1) and (A2) according to this embodiment is preferably minimized. Such impurities described herein mean the remainder other than the above-described component (a), component (b), component (c), and component (d).

Thus, the compositions according to this embodiment are preferably obtained after a purification step. Preferred examples of the purification step include filtration using a filter.

Specifically, the filtration using a filter is preferably performed in the following manner: the above-described component (a) and component (b) and an additional component that is added as necessary are mixed together, and subsequently filtered through a filter having a pore size of, for example, 0.001 μm or more and 5.0 μm or less. Such filtration using a filter is more preferably performed with multiple stages or preformed repeatedly multiple times. The filtrate may be filtered again. The filtration may be performed with a plurality of filters having different pore sizes. Non-limiting examples of such filters used for the filtration include filters formed of polyethylene resin, polypropylene resin, fluororesin, or nylon resin.

Such a purification step is performed to remove impurities such as particles from the compositions. This prevents impurities such as particles from causing unintended irregularities in a cured film obtained by curing the compositions and causing pattern defects.

Incidentally, when the compositions according to this embodiment are used for manufacturing semiconductor integrated circuits, in order not to inhibit operations of the products, entry of metal-atom-containing impurities (metal impurities) into the compositions is preferably minimized. In such a case, the concentration of the metal impurities contained in the compositions is preferably 10 ppm or less, more preferably 100 ppb or less.

### Pattern Forming Method

Hereinafter, steps of SST-NIL will be described in detail. A cured film obtained by a method for manufacturing a cured film having a pattern profile according to this embodiment is preferably a film having a pattern having a size of 1 nm or more and 10 mm or less, more preferably a film having a pattern having a size of 10 nm or more and 100 μm or less. Incidentally, in general, a pattern forming technique of forming, with light, a film having a pattern (irregular structure) having a nanometer size (1 nm or more and 100 nm or less) is referred to as a photo-nanoimprint method.

### Layer Formation Step [1]

In the layer formation step, as illustrated in FIG. 2[1], the composition (A1) in liquid form is placed on (applied to) a substrate 201 so as to form a layer, to form a liquid film 202. The substrate 201, on which the composition (A1) is placed, is a substrate to be processed, and is normally a silicon wafer. On the substrate 201, a layer to be processed may be formed. In addition, another layer may be formed between the substrate 201 and the layer to be processed. When a quartz substrate is used as the substrate 201, a replica of a quartz imprint mold (mold replica) can be produced. However, the substrate 201 is not limited to a silicon wafer or a quartz substrate. The substrate 201 is also freely selected from known substrates used for semiconductor devices and formed of aluminum, titanium-tungsten alloy, aluminum-silicon alloy, aluminum-copper-silicon alloy, silicon oxide, silicon nitride, or the like. Incidentally, the surface of the substrate 201 (substrate to be processed) used or the layer to be processed may have enhanced adhesion to the compositions (A1) and (A2) by surface treatment such as silane coupling treatment, silazane treatment, or formation of an organic thin film.

Examples of a method of placing the composition (A1) on the substrate 201 or the layer to be processed include an inkjet method, dip coating, air knife coating, curtain coating, wire bar coating, gravure coating, extrusion coating, spin coating, and slit scanning. In this embodiment, spin coating is particularly preferred. When spin coating is employed to place the composition (A1) 202 on the substrate 201 or the layer to be processed, a baking step may be performed as necessary, to evaporate the solvent component (d). Incidentally, the average film thickness of the composition (A1) varies depending on the intended use, and is, for example, 0.1 nm or more and 10,000 nm or less, preferably 1 nm or more and 20 nm or less, particularly preferably 1 nm or more and 10 nm or less.

### Supply Step [2]

In the supply step, as illustrated in FIG. 2[2], droplets 203 of the composition (A2) are preferably discretely placed on the composition (A1) layer by dropping. The placement method is preferably, in particular, an inkjet method. The droplets 203 of the composition (A2) are placed densely on the substrate opposite a region of the mold having dense recesses, and are placed sparsely on the substrate opposite a region having sparse recesses. In this case, a residual film described later can be adjusted to have a uniform thickness regardless of the pattern density on the mold.

The droplets 203 of the composition (A2) placed in the supply step rapidly spread (pre-spread), as described above, by the Marangoni's effect exerted by a driving force that is the difference in surface energy (surface tension) (FIG. 2[2]). In other words, within the composition (A1) in liquid form, the composition (A2) spread (204), to provide the mixture 213 of the composition (A1) and the composition (A2).

### Mold Contact Step [3]

Subsequently, as illustrated in FIG. 2[3], a mold 205, which has a mold pattern for transferring a pattern profile, is brought into contact with the liquid 213, which is a mixture of the composition (A1) and the composition (A2) and is formed in the earlier steps (the layer formation step and the supply step). As a result, recesses of the fine pattern in the surface of the mold 205 are filled (filled) with a liquid provided by partial mixing of the composition (A1) and the composition (A2), to provide a liquid film filling (filling) the fine pattern of the mold.

The mold (mold) 205 is preferably a mold 205 formed of a light-transmitting material in consideration of the subsequent light irradiation step. Regarding the type of material forming the mold 205, specifically, preferred examples include glass, quartz, optically transparent resins such as PMMA and polycarbonate resin, transparent metal deposited films, soft films formed of polydimethylsiloxane or the like, photocured films, and metal films. Incidentally, when an optically transparent resin is employed as the type of material forming the mold 205, the resin needs to be selected from resins that do not dissolve in the components contained in the curable composition 205. The type of material forming the mold 205 is preferably, in particular, quartz because it has a low thermal expansion coefficient and causes less pattern deformation.

The fine pattern in the surface of the mold 205 preferably has a pattern height of 4 nm or more and 200 nm or less. The smaller the pattern height, the weaker the force for separating the mold (namely, the mold release force) from the photocured film of resist in the mold release step, and the smaller the number of mold release defects that are resist pattern portions torn off by the mold release and left on the mask. The impact during release of the mold causes elastic deformation of resist patterns, which may bring neighboring resist patterns into contact with each other, and the resist patterns may be joined together or damaged. However, it is highly probable that such problems are avoided when the pattern height is substantially equal to or smaller than twice the pattern width (the aspect ratio is 2 or less). On the other hand, when the pattern height is excessively small, the process precision for the substrate to be processed is low.

In order to enhance the separability between the surface of the mold 205 and the compositions (A1) and (A2), the mold 205 may be surface-treated before the mold contact step. The surface treatment method is, for example, coating the surface of the mold 205 with a release agent to form a release agent layer. Examples of the release agent applied to the surface of the mold 205 include silicone release agents, fluorinated release agents, hydrocarbon release agents, polyethylene release agents, polypropylene release agents, paraffin release agents, montan release agents, and carnauba release agents. Commercially available release agents for coating such as OPTOOL (registered trademark) DSX manufactured by DAIKIN INDUSTRIES, LTD. may also be suitably used. Incidentally, such release agents may be used alone or in combination of two or more thereof. Of these, in particular, fluorinated and hydrocarbon release agents are preferred.

In the mold contact step, as illustrated in FIG. 2[3], when the mold 205 and the compositions (A1) and (A2) are brought into contact with each other, the pressure applied to the compositions (A1) and (A2) is not particularly limited. This pressure may be set to 0 MPa or more and 100 MPa or less. The pressure is preferably 0 MPa or more and 50 MPa or less, more preferably 0 MPa or more and 30 MPa or less, still more preferably 0 MPa or more and 20 MPa or less.

In the supply step, pre-spread of the droplets of the composition (A2) 203 has proceeded. Thus, spread of the composition (A2) 203 in this step rapidly reaches completion.

As described above, since spread and fill of the compositions (A1) and (A2) rapidly reach completion in this step, the time taken for keeping the mold 205 and the compositions (A1) and (A2) in contact with each other can be set to a short time. Thus, a large number of pattern forming steps can be completed in a short time, to achieve high productivity, which is one of advantages provided by this embodiment. The time for the contact is not particularly limited, and may be, for example, 0.1 seconds or more and 600 seconds or less. This time is preferably 0.1 seconds or more and 3 seconds or less, in particular, preferably 0.1 seconds or more and 1 second or less. When the time is less than 0.1 seconds, spread and fill are not sufficiently achieved and a large number of defects referred to as unfilled defects tend to occur.

This step may be performed under any one of conditions of the air atmosphere, a reduced-pressure atmosphere, and an inert-gas atmosphere; however, preferred are the reduced-pressure atmosphere and the inert-gas atmosphere because oxygen and moisture can be prevented from affecting the curing reaction. In the case of performing this step in the inert-gas atmosphere, specific examples of the inert gas usable include nitrogen, carbon dioxide, helium, argon, various flon gases, and gas mixtures of the foregoing. When this step is preformed in atmospheres of specific gases including the air atmosphere, the pressure is preferably 0.0001 atm or more and 10 atm or less.

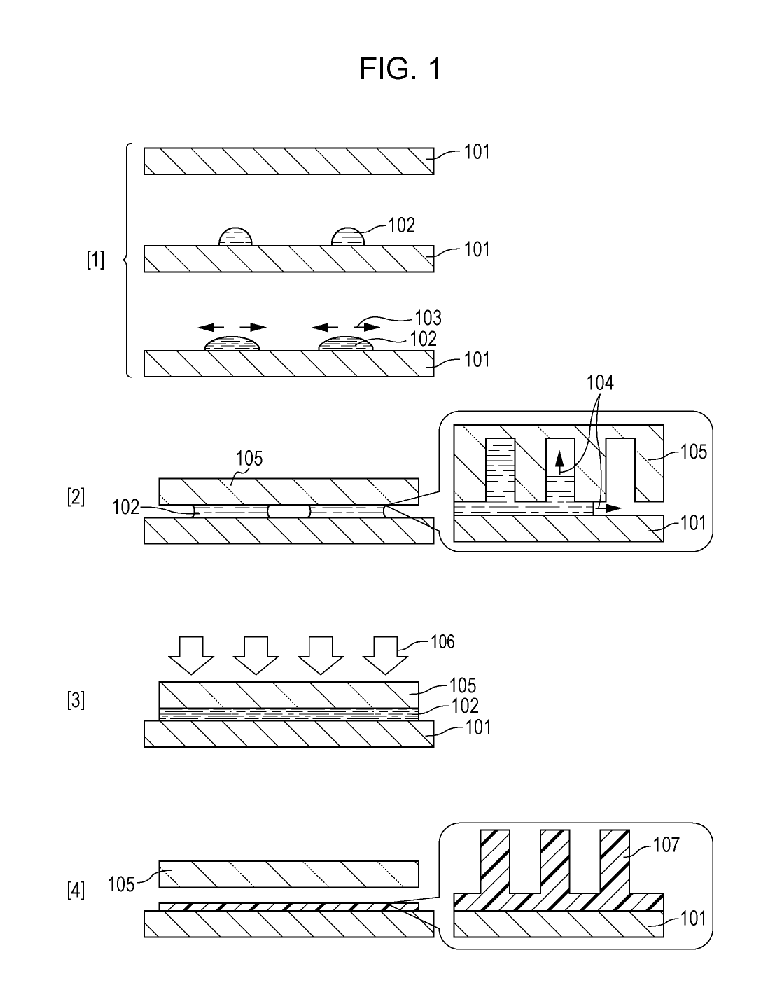

The mold contact step may be performed in an atmosphere containing a condensable gas (hereafter, referred to as the “condensable gas atmosphere”). In the Description, the term “condensable gas” denotes a gas that is condensed into liquid by capillary pressure generated during filling when the recesses of the fine pattern formed on the mold 205 and the gaps between the mold and the substrate are filled with the gas in the atmosphere together with the compositions (A1) and (A2). Incidentally, the condensable gas is present as a gas in the atmosphere (FIG. 1[2]) before the compositions (A1) and (A2) and the mold 205 come into contact with each other in the mold contact step.

When the mold contact step is performed in the condensable gas atmosphere, the gas filling the recesses of the fine pattern is liquefied by capillary pressure generated by the compositions (A1) and (A2), so that the bubbles disappear, which results in excellent filling. The condensable gas may dissolve in the composition (A1) and/or (A2).

The boiling point of the condensable gas is not limited as long as it is equal to or lower than the temperature of the atmosphere in the mold contact step, and is preferably −10° C. to 23° C., more preferably 10° C. to 23° C. When such ranges are satisfied, more excellent filling is achieved.

The vapor pressure of the condensable gas at the temperature of the atmosphere in the mold contact step is not limited as long as it is equal to or lower than the mold pressure applied during imprinting in the mold contact step, and is preferably 0.1 to 0.4 MPa. When such a range is satisfied, more excellent filling is achieved. When the vapor pressure at the temperature of the atmosphere is more than 0.4 MPa, the effect of causing the bubbles to disappear tends not to be sufficiently exerted. On the other hand, when the vapor pressure at the temperature of the atmosphere is less than 0.1 MPa, the pressure needs to be reduced, which tends to complicate the apparatus.

The temperature of the atmosphere in the mold contact step is not particularly limited, and is preferably 20° C. to 25° C.

Specific examples of the condensable gas include flons including chlorofluorocarbon (CFC) such as trichlorofluoromethane, fluorocarbon (FC), hydrochlorofluorocarbon (HCFC), hydrofluorocarbon (HFC) such as 1,1,1,3,3-pentafluoropropane (CHF₂CH₂CF₃, HFC-245fa, PFP), and hydrofluoroether (HFE) such as pentafluoroethyl methyl ether (CF₃CF₂OCH₃, HFE-245mc). Of these, preferred are 1,1,1,3,3-pentafluoropropane (vapor pressure at 23° C.: 0.14 MPa, boiling point: 15° C.), trichlorofluoromethane (vapor pressure at 23° C.: 0.1056 MPa, boiling point: 24° C.), and pentafluoroethyl methyl ether from the viewpoint of achieving excellent filling when the temperature of the atmosphere in the mold contact step is 20° C. to 25° C. In particular, preferred is 1,1,1,3,3-pentafluoropropane from the viewpoint of high safety.

Such condensable gases may be used alone or in combination of two or more thereof. Such a condensable gas may be used in combination with a non-condensable gas such as air, nitrogen, carbon dioxide, helium, or argon. The non-condensable gas mixed with the condensable gas is preferably helium from the viewpoint of filling properties. Helium permeates through the mold 205. Thus, in the mold contact step, when the recesses of the fine pattern formed on the mold 205 are filled with the gases (condensable gas and helium) in the atmosphere together with the composition (A1) and/or (A2), the condensable gas is liquefied and helium permeates through the mold.

### Light Irradiation Step [4]

Subsequently, as illustrated in FIG. 2[4], the layer formed by partial mixing of the composition (A1) and the composition (A2) is irradiated with light through the mold 205. More specifically, the composition (A1) and/or (A2) filling the fine pattern of the mold is irradiated with light 206 through the mold 205. As a result, the composition (A1) and/or (A2) filling the fine pattern of the mold 205 is cured by the irradiation light and turned into a cured film 207 having a pattern profile.

The light 206 applied to the composition (A1) and/or (A2) filling the fine pattern of the mold 205 is selected in accordance with the sensitive wavelength of the compositions (A1) and (A2). Specifically, for example, ultraviolet radiation at wavelengths of 150 nm or more and 400 nm or less, X-rays, or electron beams are preferably appropriately selected and used.

Of these, in particular, the irradiation light 206 is preferably ultraviolet radiation. This is because a large number of commercially available curing aids (photopolymerization initiators) are compounds sensitive to ultraviolet radiation. Examples of a light source that emits ultraviolet radiation include a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and a F₂ excimer laser. In particular, preferred is the ultrahigh-pressure mercury lamp. One or a plurality of light sources may be used. The light may be applied to the whole surface or only a partial region of the composition (A1) and/or (A2) filling the fine pattern of the mold.

The irradiation with light may be performed discontinuously a plurality of times on the whole region of the substrate, or may be performed continuously on the whole region. In a first irradiation step, a partial region A may be irradiated; and, in a second irradiation step, a region B different from the region A may be irradiated.

In the light irradiation step [4], as described above, leakage light, namely, dispersion of light beyond the present shot region is unavoidable due to limited costs for the mold and the apparatus.

In this embodiment, the photo-initiator component (b1) is substantially not contained (less than 0.1 weight %), so that the composition (A1) alone is not cured by irradiation with light. Thus, leakage light from the present shot does not cure the composition (A1) on the neighboring shot region. This enables formation of, also in the whole region of the neighboring shot in a short filling time, a pattern having a small number of unfilled defects.

On the other hand, in the present shot, as described above, as a result of mixing of the composition (A1) and the composition (A2), the photo-initiator (b2) component of the composition (A2) migrates to the composition (A1), so that the composition (A1) gains photosensitivity. Thus, the compositions (A1) and (A2) are both cured with irradiation light and turned into a cured film 207 having a pattern profile.

### Mold Release Step [5]

Subsequently, the cured film 207 having a pattern profile and the mold 205 are separated from each other. In the mold release step, as illustrated in FIG. 2[5], the cured film 207 having a pattern profile and the mold 205 are separated from each other, so that the cured film 207 is obtained in a free-standing state, the cured film 207 having a pattern profile that is inverse to the fine pattern formed on the mold 205 in Step [4]. Incidentally, a cured film also remains in recesses of the irregular pattern of the cured film 207 having a pattern profile. This film will be referred to as a residual film.

Incidentally, in the case where the mold contact step is performed in a condensable gas atmosphere, when the cured film 207 and the mold 205 are separated from each other in the mold release step, the pressure at an interface at which the cured film 207 and the mold 205 are in contact with each other decreases, so that the condensable gas evaporates. This tends to exert the effect of reducing the mold release force, which is a force required to separate the cured film 207 and the mold 205 from each other.

The method of separating the cured film 207 having a pattern profile and the mold 205 from each other is not particularly limited as long as the cured film 207 having a pattern profile is not partially physically damaged during the separation; and various conditions and the like are also not particularly limited. For example, the substrate 201 (substrate to be processed) may be fixed, and the mold 205 may be moved away from the substrate 201 to achieve the separation. Alternatively, the mold 205 may be fixed, and the substrate 201 may be moved away from the mold to achieve the separation. Alternatively, both of these may be pulled in the opposite directions to achieve the separation.

The above-described series of steps (manufacturing process) including Step [1] to Step [5] provides a cured film having a desired irregular pattern profile (pattern profile corresponding to the irregular profile of the mold 205) at a desired position.

### Imprint Apparatus

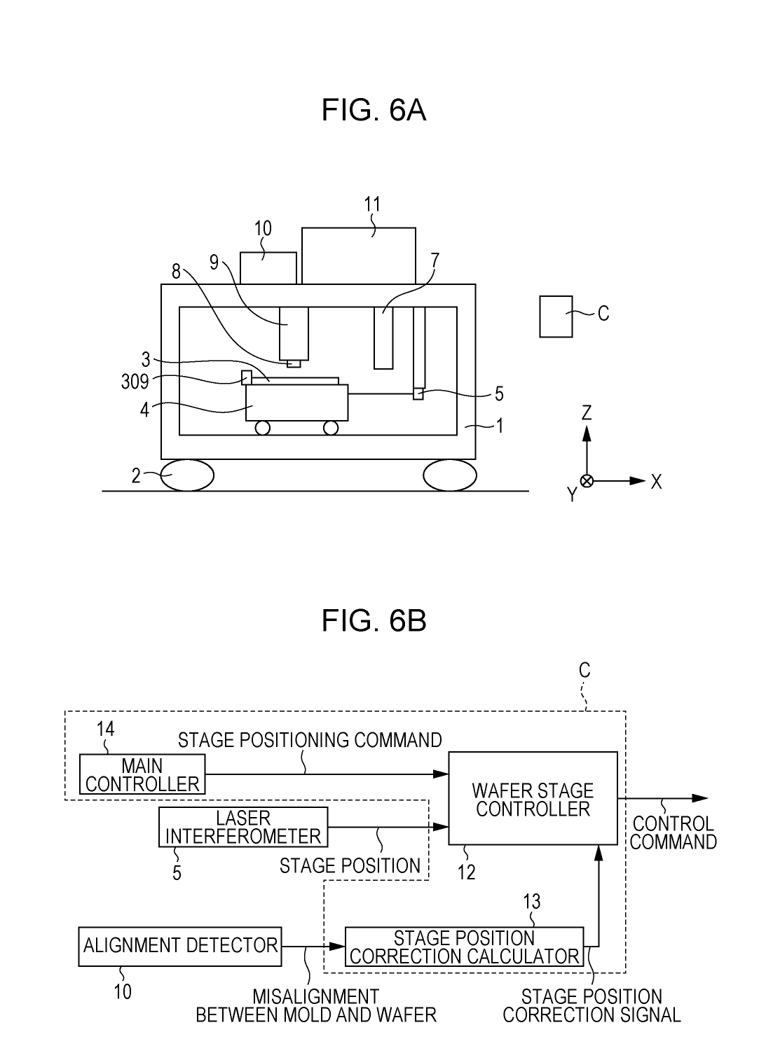

Hereinafter, as an example of an apparatus configured to perform the above-described pattern forming method, an imprint apparatus will be described. FIG. 6A schematically illustrates an imprint apparatus according to the first embodiment. A body 1 of the imprint apparatus is disposed on the floor with a three-legged or four-legged damping mechanism 2 therebetween, the damping mechanism 2 using an air spring or the like. A substrate (wafer) 3 is held, with a wafer chuck (not shown), on a substrate stage (wafer stage) 4. The wafer stage 4 has X-direction and Y-direction strokes long enough to enable imprint treatment for the whole surface of the wafer 3, and enable movement to an exchange position at which the wafers 3 are loaded or unloaded with a wafer exchange hand (not shown).

In FIG. 6A, the wafer stage 4 is simply illustrated as a box with wheels, but actually has the following structure. In the wafer stage 4, on a coarse stage having long strokes in the X direction and the Y direction, a fine stage is mounted that has short strokes and provides high positioning accuracy. The configuration of the wafer stage 4 is not limited to this, and may employ a high-accuracy positioning stage commonly used as a wafer stage for semiconductor aligners.

The X-direction position of the wafer stage 4 is measured with a laser interferometer 5 disposed in the body 1 and a reflex mirror (not shown) disposed on the wafer stage 4 and configured to reflect a laser beam. Similarly, another laser interferometer is disposed for measurement in the Y direction. The position of the wafer stage 4 may be measured with an encoder system including a scale substrate disposed in the body 1 and an optical device disposed on the wafer stage 4.

On the wafer stage 4, a vibration generator 309 (operation unit) is disposed, which generates high frequency vibrations to vibrate the substrate. A photocurable resin (imprint material) used during imprint treatment is supplied, through a dispenser 7 (supply unit) disposed in the body 1, onto the wafer 3. A mold (also referred to as a mold or a template) 8 having a fine pattern is held with a mold stage (imprint head mechanism) 9 disposed in the body 1. The mold stage 9 is configured to hold the mold 8 and simultaneously move the mold 8 in the Z direction. Here, as illustrated in FIG. 1, the direction in which the mold 8 held on the mold stage 9 is pressed to the resin-supplied wafer 3 is defined as the Z direction. The directions that are orthogonal to the direction in which the mold 8 is pressed to the wafer 3 and that are parallel to the surface of the wafer 3 are defined as the X direction and the Y direction.

The relative position of the wafer 3 relative to the mold 8 in the directions parallel to the surface of the wafer 3 (in the X direction and the Y direction) is determined with a detector 10 disposed in the body 1. The wafer 3 has alignment marks positioned at shot regions and transferred in an earlier treatment step. Correspondingly, the mold 8 also has alignment marks. The detector 10 emits alignment light to the mold 8 and the wafer 3 and detects their alignment marks with an alignment scope. A controller C performs image processing on the detection results of the alignment scope, to thereby calculate the relative misalignment between the mold 8 and the wafer 3. An irradiation system 11 configured to emit ultraviolet radiation to cure the resin is mounted on the body 1.

FIG. 6B illustrates the control system of the imprint apparatus. The position control of the wafer stage 4 is performed with a wafer stage controller 12. The wafer stage controller 12 employs a feedback control system based on feedback of deviation obtained by subtracting the stage position measured with the laser interferometer 5 from a stage positioning command sent by a main controller 14. The misalignment between the mold 8 and the wafer 3, the misalignment being outputted from the detector 10, is inputted to a stage position correction calculator 13, and sent as a stage position correction signal to the wafer stage controller 12. The wafer stage controller 12 performs control computation of adding the stage position correction signal to the above-described stage positioning command to provide the target position of the wafer stage 4. The control command resulted from the control computation is sent to an actuator configured to actuate the wafer stage 4 to provide an actuation force, to thereby control the position of the wafer stage 4.

Hereinafter, operations of the imprint treatment will be described. The wafer stage 4 moves to the position where the wafers 3 are exchanged; the wafer 3 is loaded, with the wafer exchange hand (not shown), to the wafer chuck (not shown). The controller C moves the wafer stage 4 such that, on the wafer 3, a shot region to be subjected to the imprint treatment is positioned beneath the dispenser 7; and the dispenser 7 supplies resin to the wafer 3. The controller C moves the wafer stage 4 such that the shot region is positioned beneath the mold 8; subsequently, the mold stage 9 lowers the mold 8 to perform imprinting. This imprinting means that the mold stage 9 is driven in the Z direction to bring the mold 8 into contact with the resin on the wafer surface to form a gap of 1 μm or less between the mold 8 and the wafer 3, and to fill the gap with the resin. At the initiation of the imprinting, there is relative misalignment between the positions of the mold 8 and the wafer 3 in the horizontal directions (X direction and Y direction). As described above, this misalignment is determined with the detector 10, and a stage correction signal generated by the stage position correction calculator 13 is sent to the wafer stage controller 12.

Hereinafter, in the supply step [2], the nonuniform concentration of the mixture will be described. As described above, in the supply step [2], the region 209 having a high composition (A1) concentration may be generated between a droplet and a droplet of the composition (A2) 203. The composition (A1) and the composition (A2) are different compositions, and they are mixed together, after dropping of the composition (A2), by the light irradiation step. When the composition (A1) substantially does not have photoreactivity, as a result of mixing of the composition (A1) and the composition (A2), the photo-initiator (b) component of the composition (A2) migrates to the composition (A1), so that the composition (A1) gains photosensitivity for the first time. Since the mixing between the composition (A1) and the droplets of the composition (A2) within a shot region depends on mutual diffusion based on the composition difference, a long time of several seconds to several tens of seconds is taken to reach a uniform composition. When the time for diffusion is insufficient, as illustrated in FIG. 2[3], a region 209 in which the compositions are not sufficiently mixed is generated. When the composition of such a region 209 in which the composition (A1) and the composition (A2) are not sufficiently mixed together is irradiated with light and cured, the cured film has nonuniform film properties such as dry etching resistance, which is problematic.

In general, the composition (A1) and the composition (A2) often have a difference in dry etching resistance. For example, when the composition (A1) has lower dry etching resistance than the composition (A2), the insufficient mixing region 209 has low dry etching resistance. Such a region having low dry etching resistance will form defects during etching in a subsequent step. In order to avoid such defects, the compositions need to be mixed together sufficiently. In order to diffuse the composition (A2) into the composition (A1), the composition (A1) and the composition (A2) need to be kept in contact with each other in liquid form for a long time. However, the mixing performed for a long time causes an increase in the time taken for one shot. This causes a considerable decrease in the throughput, which is problematic.

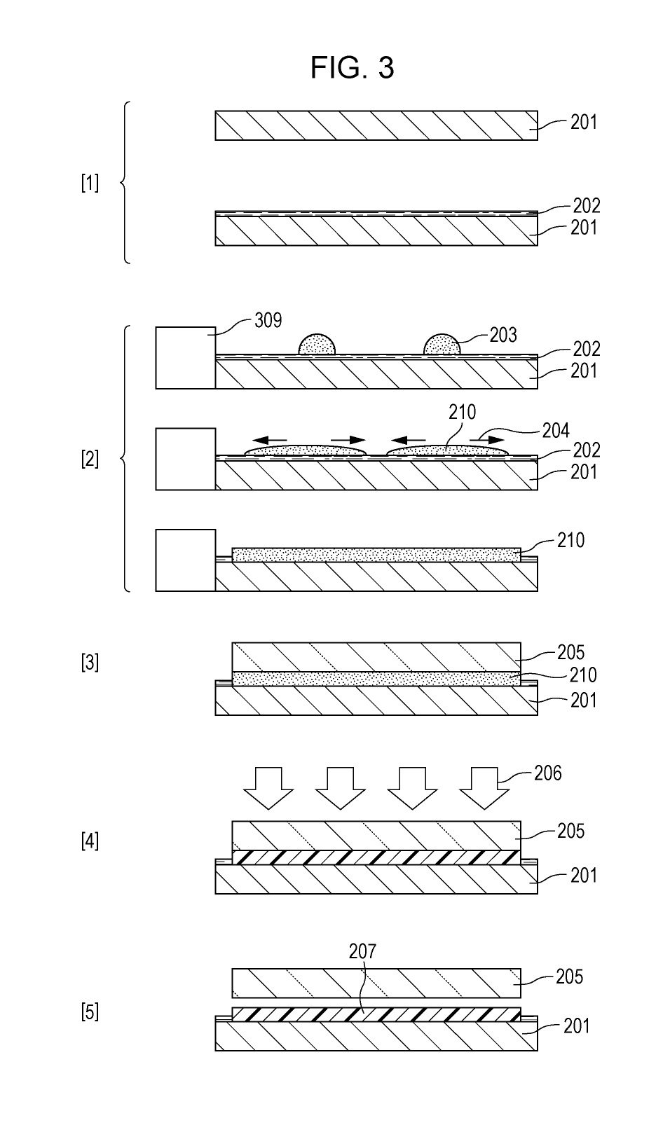

Accordingly, as illustrated in FIG. 3, in the supply step [2], while the droplets 203 of the composition (A2) are placed on the composition (A1) 202 (liquid film), a vibration generator 309 (operation unit) is used to vibrate the substrate 201. The substrate 201 is vibrated to thereby vibrate the composition (A1) 202 and the composition (A2) 203 in liquid form. This promotes mixing of the composition (A1) and the composition (A2) in liquid form. As a result, the composition (A1) and the composition (A2) are mixed together in wider regions, to thereby provide a mixture 210 having a more uniform concentration in a shorter time. In other words, the vibration generator 309 vibrates the substrate such that the composition (A1) and the composition (A2) in liquid form are mixed together in wider regions.

The vibration generator 309 includes an actuator; and the actuator is driven to generate vibrations. Examples of the actuator include piezo actuators, DC motors, and AC motors. In FIG. 3[2], the vibration generator 309 is disposed so as to be in direct contact with the substrate 201. However, as long as vibrations are transmitted to the compositions on the substrate, such a direct contact with the substrate 201 is not necessary. For example, the vibration generator 309 may be disposed on a substrate stage configured to hold and move the substrate 201, or may be disposed on a substrate chuck configured to hold the substrate by vacuum suction.

The vibration generator 309 may provide vibrations at a low frequency or a high frequency. High-frequency vibrations such as ultrasonic waves may be provided. Vibrations may be provided not only in a direction along the plane of the substrate, but also in a direction perpendicular to (a direction along a line normal to) the plane of the substrate. The substrate may be vibrated so as to be rotated around a freely selected axis. The direction, frequency, amplitude, and time of vibrations are determined in accordance with, for example, the viscosities of the composition (A1) and the composition (A2) and the amount of droplets of the composition (A2) dropped. Thus, in advance, while the composition (A1) and composition (A2) and the mold are in contact with each other, the direction, frequency, amplitude, and time of vibrations are preferably changed and the mixing state is examined, and the values to be actually used are determined. The mixing state can be observed with a camera disposed in the imprint apparatus. The following control may be performed: on the basis of the images captured with the camera, the mixing state of the compositions is determined; when the mixing state is satisfactory, vibrations for the substrate are stopped; or, when the mixing state is not satisfactory, vibrations for the substrate may be continuously performed, or the direction, frequency, or amplitude of vibrations may be changed.

The amplitude of vibrations is not particularly limited. However, when the amplitude is excessively large, the composition (A2) may come out from a shot region 503. When the composition comes out from the shot region, it may adhere to the wall surface of the mold; the adhering curable composition may make it impossible for the mold to come into planar contact with the substrate. In this case, the mold needs to be subjected to a washing process. For this reason, the amplitude of vibrations in the planar direction is desirably equal to or less than half the size of the shot region, more preferably, suppressed to 1 μm or less. As a result, coming out of the composition is reduced, so that the composition is prevented from adhering to the wall surface of the mold, to increase the number of shots performed until the mold needs to be washed once.

As has been described, this embodiment promotes mixing of the compositions on the substrate, to reduce the time taken for curing the compositions. This enables an increase in the throughput of pattern forming.

The above-described mixture 210 provided by mixing in wider regions is subjected to the mold contact step [3], the light irradiation step [4], and the mold release step [5], to thereby precisely form a pattern 207 having less defects.

### Second Embodiment

A pattern forming method according to this embodiment is the same as in the first embodiment except that the supply step [2] and the mold contact step [3] are different from the steps in FIG. 3. Hereinafter, such differences will be described.

### Supply Step [2]

In this embodiment, after the composition (A2) is dropped on the composition (A1), the substrate 201 in the as-dropped state without application of vibrations is subjected to the subsequent mold contact step [3].

### Mold Contact Step [3]

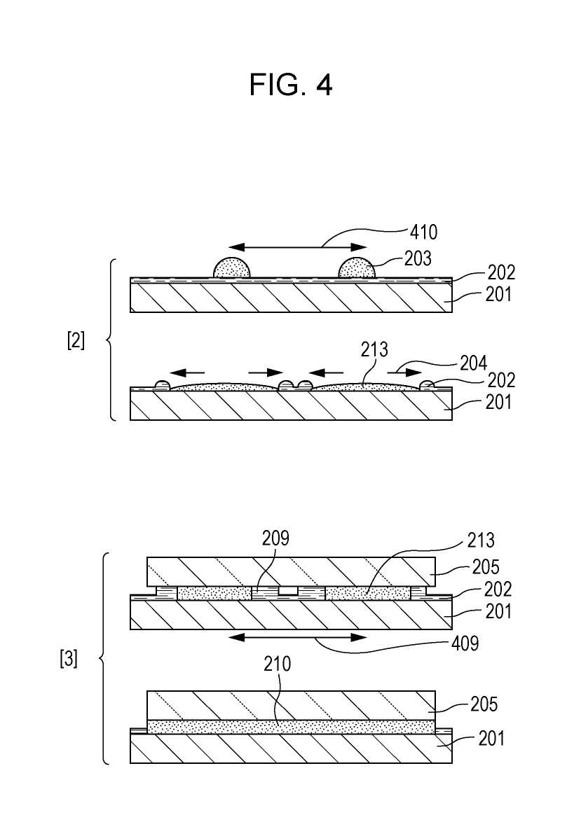

As illustrated in FIG. 4[3], the mold 205, which has a mold pattern for transferring the pattern profile, is brought into contact with the liquid 213, which is formed in the earlier steps (the layer formation step and the supply step) as a result of partial mixing of the composition (A1) and the composition (A2). Upon contact with the mold 205, the mixture 213 of the composition (A1) and the composition (A2) is pressed to spread; however, the region 209 in which mixing is not sufficiently achieved is generated between a droplet and a droplet of the dropped composition (A2). In order to achieve mixing of the compositions in such inter-droplet regions, as illustrated in FIG. 4[3], while the composition (A1) and the composition (A2) are sandwiched between, and in contact with, the substrate 201 and the mold 205, the substrate 201 is moved in its surface (planar) direction 409 relative to the mold. As a result, the mold or the substrate applies a shearing stress to the compositions, to promote the mixing of the composition (A1) and the composition (A2), to provide the mixture 210 of the composition (A1) and the composition (A2). The movement of the substrate is performed with the substrate stage (operation unit) holding the substrate. Incidentally, in the movement, the substrate 201 and the mold 205 are relatively moved in the surface (planar) direction of the substrate 201; and the mold may be moved relative to the substrate. In other words, while the composition (A1) and composition (A2) and the mold 205 are in contact with each other, the mold and the substrate are relatively moved such that mixing of the composition (A1) and the composition (A2) is caused in wider regions. The mold is moved by the mold stage (operation unit) holding the mold. Instead of moving any one of the substrate and the mold, both of them may be simultaneously moved. When both of the substrate and the mold are simultaneously moved in the planar direction, the substrate and the mold are desirably moved in opposite directions or different directions to thereby increase the shearing stress to the compositions sandwiched therebetween.

Such a movement direction may be, instead of the planar direction of the substrate relative to the mold, a direction perpendicular to the plane of the substrate; or the movement may be performed in both of the planar direction and the perpendicular direction. Alternatively, the movement may be performed so as to be rotated around a freely selected axis. The movement in the planar direction may be performed in a specific one direction; however, in order to achieve more efficient mixing of the compositions, the movement is desirably performed in a plurality of directions simultaneously. For example, the substrate is moved so as to draw a circle. The movement in the perpendicular direction is desirably performed such that the compositions in liquid form on the substrate are in contact with the mold, and the meniscus formed between the mold and the substrate due to the surface tension of the compositions is maintained, in other words, the contact with the liquids is maintained. An excessively large amplitude of the movement causes corruption of the meniscus and the liquid compositions become separated from the mold or the substrate. Such a liquid separation may cause entry of bubbles in the pattern of the mold.

The direction, period, amplitude, and time of the movement are determined in accordance with, for example, the viscosities of the compositions (A1) and (A2), the amount of droplets of the composition (A2) dropped, and the distance between the mold and the substrate. Thus, in advance, while the composition (A1) is placed on a substrate so as to form a layer, the composition (A2) is dropped, and the compositions are sandwiched between a mold and the substrate, the direction, period, amplitude, and time of the movement are preferably changed and the mixing state is examined, and the values to be actually used are determined. The mixing state can be observed with a camera disposed in the imprint apparatus. The following control may be performed: on the basis of the images captured with the camera, the mixing state of the compositions is determined; when the mixing state is satisfactory, the movement of at least one of the substrate and the mold is stopped; or, when the mixing state is not satisfactory, the relative movement may be continuously performed, or the direction, period, amplitude, and time of the movement may be changed.

When a plurality of shot regions are disposed within the same substrate, the compositions need to be controlled so as not to come out from the shot regions of the substrate. Thus, the amplitude of the movement (amount of movement) in the planar direction is desirably, as illustrated in FIG. 4[2], set to a distance similar to a pitch 410, or half the pitch, between the droplets 203 of the composition (A2). However, the distance is set to a distance that does not cause coming out of the composition (A2) from the shot regions, desirably a distance equal to or smaller than half the spacing of a plurality of shot regions, more preferably, suppressed to 1 μm or less. When the composition comes out from a shot region, it adversely affects the neighboring shot region. Specifically, the composition (A2) coming out from a shot region may adhere to the wall surface of the mold, and the adhering composition may make it impossible for the mold to come into planar contact with the substrate. In this case, the mold needs to be subjected to a washing process. Thus, coming out of the composition may be minimized in order to increase the number of shots performed until the washing needs to be performed once. In order to prevent the adhesion to the wall surface of the mold, the amount of coming out is preferably controlled to be 1 μm or less.

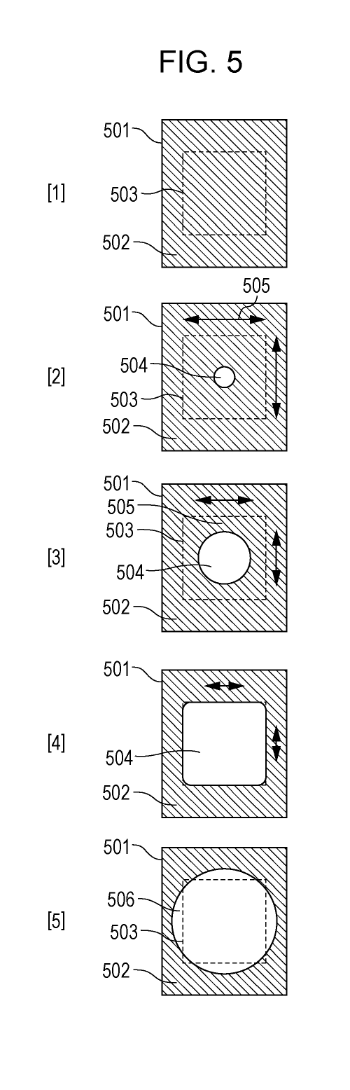

The relationship between a shot region and a liquid contact region will be described with reference to FIG. 5. FIG. 5[1] illustrates a state in which, on a shot region 503 of a substrate 501, a composition 502 is disposed. FIG. 5[2] illustrates, upon contact between the composition 502 and the mold, a liquid contact region 504. When the movement is performed in the planar direction, at an instant of contact between the mold and the curable composition on the substrate, as illustrated as an amplitude 505 in [2], a large amplitude is selected. Subsequently, as the mold is pressed, the distance between the mold and the substrate is shortened and the liquid contact region 504 spreads. At this time, as illustrated in FIG. 5[3] and [4], the following control is preferably performed: while the distance between the mold and the substrate is shortened, the amplitude 505 of the relative movement between the mold and the substrate is decreased. When the amplitude of the relative movement is excessively large, as illustrated in FIG. 5[5], a composition 506 extending beyond the shot region is formed.

When a semiconductor chip is manufactured, during imprinting of the mold into the compositions on the substrate, the substrate and the mold need to be precisely aligned. Such alignment is desirably performed after the substrate stage or the mold stage is moved to mix together the composition (A1) and the composition (A2).

In the above-described case, while the composition (A1) and composition (A2) and the mold 205 are brought into contact with each other, the mold and the substrate are relatively moved. Alternatively, while the composition (A1) and composition (A2) and the mold 205 are brought into contact with each other, the substrate may be vibrated. The substrate may be vibrated as in the first embodiment. Incidentally, in the mold contact step [3], as described above, the substrate and the mold are aligned. Thus, when the substrate is vibrated during alignment between the substrate and the mold, such vibrations may affect the detection results by an optical sensor for detecting the alignment marks of the substrate and the mold. The optical sensor is configured to accumulate detected light from the substrate and the mold for a predetermined time, and convert the average values to electric signals. Thus, when the vibrations are at a frequency of 1 kHz or more, the vibrations affect less the detection results by the optical sensor due to the averaging effect. Thus, when the substrate is vibrated while the composition (A1) and composition (A2) and the mold 205 are brought into contact with each other, vibrations at a frequency of 1 kHz or more are desirably applied. When vibrations at a frequency of 1 kHz or less are applied, alignment between the substrate and the mold may be temporarily terminated, and the alignment may be resumed after the substrate is vibrated to achieve uniform mixing of the whole compositions.

As has been described, this embodiment promotes mixing of the compositions on the substrate to reduce the time taken for curing the compositions. This enables an increase in the throughput of pattern forming.

The above-described mixture provided by mixing in wider regions is subjected to the light irradiation step [4] and the mold release step [5] to thereby precisely form a pattern having less defects.

### Third Embodiment

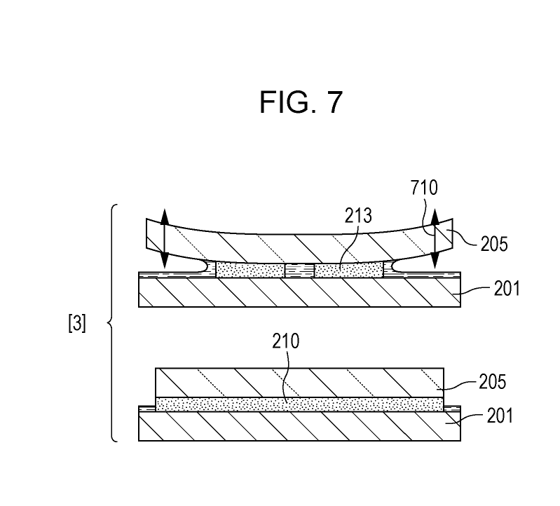

This embodiment is different from the second embodiment in terms of the way of moving the mold in the mold contact step [3]. This will be described with reference to FIG. 7.

In this embodiment, in the mold contact step [3], while the mold and the compositions on the substrate are in contact with each other, in order to make the gas between the mold and the substrate more escapable, the mold is bent so as to be convex toward the substrate. The mold has, on a side opposite to a pattern portion having the pattern, a space in which gas is controlled in terms of pressure; and a controller (operation unit) configured to control the pressure of gas within the space is used to control the bending amount (shape) of the mold. Thus, while the mold is bent and the liquid contact is kept, the pressure within the space is controlled to change the bending amount of the mold to thereby apply vibrations 710 to the mold. As a result, vibrations of the mold can be transmitted to the compositions on the substrate, to thereby promote mixing of a plurality of compositions on the substrate.

Incidentally, the operation unit configured to vibrate the mold may not necessarily employ control of the pressure within the space, and may be a vibration generator configured to vibrate the mold or an actuator configured to deform the mold, and disposed on the mold stage.

The mold may be vibrated at a low frequency or a high frequency. High-frequency vibrations such as ultrasonic waves may be provided. The direction of the vibrations may be freely selected. The direction, frequency, amplitude, and time of vibrations are determined in accordance with, for example, the viscosities of the composition (A1) and the composition (A2) and the amount of droplets of the composition (A2) dropped. Thus, in advance, while the composition (A1) and composition (A2) and the mold are in contact with each other, the direction, frequency, amplitude, and time of vibrations are preferably changed and the mixing state is examined, and the values to be actually used are determined. The mixing state can be observed with a camera disposed in the imprint apparatus. The following control may be performed: on the basis of the images captured with the camera, the mixing state of the compositions is determined; when the mixing state is satisfactory, vibrations for the mold are stopped; or, when the mixing state is not satisfactory, vibrations for the substrate may be continuously performed, or the direction, frequency, or amplitude of vibrations may be changed. As in the second embodiment, when the mold is vibrated while the composition (A1) and composition (A2) and the mold 205 are brought into contact with each other, vibrations at a frequency of 1 kHz or more are desirably applied. When vibrations at a frequency of 1 kHz or less are applied, alignment between the substrate and the mold may be temporarily terminated, and the alignment may be resumed after the mold is vibrated to achieve uniform mixing of the whole compositions.

Alternatively, while the mold is bent and the liquid contact is kept, the amount of the mold bent is decreased and, as in the second embodiment, the substrate stage may be moved.

As has been described, this embodiment promotes mixing of the compositions on the substrate to reduce the time taken for curing the compositions. This enables an increase in the throughput of pattern forming. The mixture provided by mixing in wider regions is subjected to the light irradiation step [4] and the mold release step [5] to thereby precisely form a pattern having less defects.

### Article Manufacturing Method

Hereinafter, a method for manufacturing an article using the above-described pattern forming method or imprint apparatus (for example, a semiconductor IC element, a liquid crystal display element, a color filter, MEMS, an optical component, or a mold) will be described. The article is manufactured in the following manner: the above-described pattern forming method is performed to conduct the step of exposing a substrate (for example, a wafer or a glass substrate) having the mixed curable composition thereon, and the step of curing the composition to form a pattern on the substrate; and the substrate having the pattern is treated by other well-known processing steps. The other well-known steps include, for example, etching, dicing, bonding, and packaging. This manufacturing method enables manufacturing of articles of higher quality than the existing articles.

The embodiments have been described so far; however, these do not place limitations and these embodiments may be combined. For example, the supply step [2] of the first embodiment may be combined with the mold contact step [3] of the second embodiment. For example, after the composition (A2) is dropped on the composition (A1), the substrate may be vibrated to achieve mixing of the composition (A1) and the composition (A2) dropped thereon. After the mixing, in the mold contact step [3] of the second embodiment, the substrate stage or the mold stage may be moved to thereby perform further mixing of the compositions (A1) and (A2). This enables mixing to a more uniform concentration, to reduce the mixing time of the compositions in the mold contact step [3] in the second embodiment.

The compositions may be mixed not only within the imprint apparatus, but also outside the imprint apparatus. For example, within an apparatus of supplying the composition (A1) or the composition (A2) onto the substrate, the substrate in which the composition (A2) is supplied onto the liquid film of the composition (A1) may be vibrated. Alternatively, while a mold (object) not having a pattern and the compositions on the substrate are brought into contact with each other, the substrate and the object may be relatively moved, or the object may be vibrated.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of U.S. Provisional Application No. 62/467,699 filed Mar. 6, 2017, which is hereby incorporated by reference herein in its entirety.

What is claimed is:

1. A pattern forming method of forming a pattern on a substrate by using a mold, the pattern forming method comprising:
a step of supplying a curable composition onto a liquid film formed on a substrate,
a step of vibrating the substrate so as to mix together a composition of the liquid film and the curable composition,
a step of bringing a mixture into contact with the mold, the mixture being provided by vibrating the substrate to mix together the composition of the liquid film and the curable composition, and
a step of curing the mixture being in contact with the mold to form a pattern.

2. The pattern forming method according to claim 1, wherein the substrate is vibrated while the mold and the substrate are aligned with each other.

3. The pattern forming method according to claim 2, wherein the substrate is vibrated at 1 kHz or higher.

4. A pattern forming method of forming a pattern on a substrate by using a mold, the pattern forming method comprising:
a step of supplying a curable composition onto a liquid film formed on a substrate,
a step of, while the curable composition on the liquid film and the mold are brought into contact with each other, relatively moving the mold and the substrate so as to mix together a composition of the liquid film and the curable composition, and
a step of curing a mixture to form a pattern, the mixture being provided by relatively moving the mold and the substrate to mix together the composition of the liquid film and the curable composition.

5. The pattern forming method according to claim 4, wherein, while a distance between the substrate and the mold is shortened, a movement amount of relatively moving the mold and the substrate is decreased.

6. The pattern forming method according to claim 4, wherein the mold and the substrate are relatively moved in a planar direction of the substrate, and
a movement amount of relatively moving the mold and the substrate is equal to or smaller than half a spacing between a plurality of shot regions of the substrate.

7. The pattern forming method according to claim 4, wherein the mold and the substrate are relatively moved in a planar direction of the substrate, and
a movement amount of relatively moving the mold and the substrate is 1 μm or less.

8. The pattern forming method according to claim 4, wherein droplets of the curable composition are discretely supplied onto the liquid film formed on the substrate,
the mold and the substrate are relatively moved in a planar direction of the substrate, and
a movement amount of relatively moving the mold and the substrate is half a pitch of the droplets of the curable composition.

9. A pattern forming method of forming a pattern on a substrate by using a mold, the pattern forming method comprising:
a step of supplying a curable composition onto a liquid film formed on a substrate,
a step of, while the curable composition on the liquid film and the mold are brought into contact with each other, vibrating the mold so as to mix together a composition of the liquid film and the curable composition, and
a step of curing a mixture to form a pattern, the mixture being provided by vibrating the mold to mix together the composition of the liquid film and the curable composition.

10. The pattern forming method according to claim 9, wherein the mold is vibrated by controlling a bending amount of the mold.

11. The pattern forming method according to claim 1, wherein droplets of the curable composition are discretely supplied onto the liquid film formed on the substrate.

12. The pattern forming method according to claim 1, wherein the composition of the liquid film contains a polymerizable compound.

13. The pattern forming method according to claim 1, wherein a photopolymerization initiator content of the composition of the liquid film relative to a total weight of the composition of the liquid film is 0 weight % or more and less than 0.1 weight %.

14. The pattern forming method according to claim 1, wherein a mixing state of the composition of the liquid film and the curable composition is detected, and vibration of the substrate is controlled on a basis of a detection result.

15. The pattern forming method according to claim 4, wherein a mixing state of the composition of the liquid film and the curable composition is detected, and relative movement between the mold and the substrate is controlled on a basis of a detection result.

16. The pattern forming method according to claim 9, wherein a mixing state of the composition of the liquid film and the curable composition is detected, and vibration of the mold is controlled on a basis of a detection result.

17. An imprint apparatus for forming a pattern on a substrate by using a mold, the imprint apparatus comprising:
a supply unit configured to supply a curable composition onto a liquid film formed on the substrate, and
an operation unit configured to vibrate the substrate so as to mix together a composition of the liquid film and the curable composition,
wherein a mixture is brought into contact with the mold, the mixture being provided by vibrating the substrate to mix together the composition of the liquid film and the curable composition, and the mixture being in contact with the mold is cured to form a pattern.

18. An imprint apparatus for forming a pattern on a substrate by using a mold, the imprint apparatus comprising:
a supply unit configured to supply a curable composition onto a liquid film formed on the substrate, and
an operation unit configured to, while the curable composition on the liquid film and the mold are brought into contact with each other, relatively move the mold and the substrate so as to mix together a composition of the liquid film and the curable composition,
wherein a mixture is brought into contact with the mold, the mixture being provided by relatively moving the mold and the substrate to mix together the composition of the liquid film and the curable composition, and the mixture being in contact with the mold is cured to form a pattern.

19. An imprint apparatus for forming a pattern on a substrate by using a mold, the imprint apparatus comprising:
a supply unit configured to supply a curable composition onto a liquid film formed on the substrate, and
an operation unit configured to, while the curable composition on the liquid film and the mold are brought into contact with each other, vibrate the mold so as to mix together a composition of the liquid film and the curable composition,
wherein a mixture is brought into contact with the mold, the mixture being provided by vibrating the mold to mix together the composition of the liquid film and the curable composition, and the mixture being in contact with the mold is cured to form a pattern.

20. A method for manufacturing an article, the method comprising:
a step of forming a pattern on a substrate by the pattern forming method according to claim 1, and
a step of treating the substrate having the pattern to manufacture an article.

21. A method for manufacturing an article, the method comprising:
a step of forming a pattern on a substrate by the pattern forming method according to claim 4, and
a step of treating the substrate having the pattern to manufacture an article.

22. A method for manufacturing an article, the method comprising:
a step of forming a pattern on a substrate by the pattern forming method according to claim 9, and
a step of treating the substrate having the pattern to manufacture an article.

23. A mixing method of mixing together a composition of a liquid film formed on a substrate and a curable composition, the mixing method comprising:
a step of supplying the curable composition onto the liquid film, and
a step of vibrating the substrate to mix together the composition of the liquid film and the curable composition.

24. A mixing method of mixing together a composition of a liquid film formed on a substrate and a curable composition, the mixing method comprising:
a step of supplying the curable composition onto the liquid film, and
a step of, while the liquid film and the curable composition, and an object are brought into contact with each other, relatively moving the object and the substrate so as to mix together the composition of the liquid film and the curable composition, to mix together the composition of the liquid film and the curable composition.

25. A mixing method of mixing together a composition of a liquid film formed on a substrate and a curable composition, the mixing method comprising:
a step of supplying the curable composition onto the liquid film, and
a step of, while the liquid film and the curable composition, and an object are brought into contact with each other, vibrating the object to mix together the composition of the liquid film and the curable composition.
